(19) United States
(12) Patent Application Publication
(10) Pub. No.: US 2024/0096932 A1
(43) Pub. Date: Mar. 21, 2024

(54) SEMICONDUCTOR ELEMENTS WITH FIELD SHIELDING BY POLARIZATION DOPING

(71) Applicant: Robert Bosch GmbH, Stuttgart (DE)

(72) Inventors: Dragos Costachescu, Reutlingen (DE); Humberto Rodriguez Alvarez, Kornwestheim (DE); Jens Baringhaus, Sindelfingen (DE); Muhammad Alshahed, Stuttgart (DE)

(21) Appl. No.: 18/467,961

(22) Filed: Sep. 15, 2023

(30) Foreign Application Priority Data
Sep. 19, 2022 (DE) 10 2022 209 800.5

(51) Int. Cl. H01L 29/06; H01L 29/20; H01L 29/66; H01L 29/78

(52) U.S. Cl. CPC H01L 29/0615; H01L 29/2003; H01L 29/66712; H01L 29/7802

(57) ABSTRACT

A semiconductor component, in particular diode or transistor. The semiconductor component includes two electrodes configured vertically one above the other, a substrate (102) made of gallium nitride, and a shielding layer for forming a space charge zone for shielding of an electric field when the semiconductor component is connected in a blocking operation or reverse direction.

### FIELD

The present invention relates to a semiconductor component having a vertical construction or having two gallium-based electrodes configured vertically indirectly one above the other, and having a barrier layer for locating a peak or peak value of the electric field when the semiconductor component is connected in a reverse direction or when the semiconductor component is operated in a blocking state. Furthermore, the present invention relates to a method for manufacturing a corresponding semiconductor component having two electrodes configured vertically one above the other and a corresponding barrier layer.

### BACKGROUND INFORMATION

For semiconductor components, in particular diodes or transistors, gallium nitride is a preferred material system or substrate material, since semiconductor components based on gallium nitride fundamentally exhibit low electrical resistance in the forward direction or in a forward operating state (on-resistance) with simultaneously higher breakdown voltages or breakdown field strengths in the blocking state of the semiconductor component. In principle, semiconductor components based on gallium nitride are described in the related art. Furthermore, with regard to the design of semiconductor components, in addition to a classic, substantially horizontal configuration of the electrodes, a vertical configuration one over the other of at least two electrodes of a component is also a common design alternative in order to make it possible to provide correspondingly miniaturized semiconductor components.

Furthermore, in the related art for diodes and transistors based on or having a substrate of gallium nitride and with a vertical configuration one over the other of at least two electrodes, barrier layers, for example at the transition between a drift layer and a channel region, lead to a depletion layer or space charge zone in order to be able to realize the highest possible breakdown field strength of the electric field in the blocking state and thus to be able to operate the semiconductor component at correspondingly high voltages.

For the substrate material or material system gallium nitride, up to now, such a barrier layer has been realized by ion implantations of magnesium ions into the gallium nitride lattice of a drift layer. The disadvantage here is the fact that the electrical activation of these doping ions is technically challenging due to the high activation energy, so that only a fraction of the implanted ions can be activated. Consequently, for the effective formation of a barrier layer, significantly more ions must be implanted or introduced than is absolutely necessary to achieve a sufficient dopant concentration following activation. In addition, the introduction of doping ions during ion implantation damages the crystal, in particular the crystal structure or crystal lattice of the drift layer, which in turn leads to a reduced breakdown field strength of the electric field in the blocking state or blocking operation, thus limiting the maximum voltage with which the component can be operated.

### SUMMARY

A semiconductor component according to the present invention based on gallium nitride and with two electrodes configured vertically one above the other may have an advantage that, without a corresponding ion implantation and without a corresponding introduction of doping ions via a polarization doping, a region effectively or in sum formed like a junction layer can be realized, which correspondingly realizes the effect of the barrier layer and shifts a peak or maximum value of the electric field in the reverse direction into the region of the drift layer or even distributes it over the region of the drift layer, so that the semiconductor component can be operated with correspondingly high voltages.

Against the background of the above explanations, it is therefore provided, in a semiconductor component according to an example embodiment of the present invention with two electrodes configured vertically one above the other and a substrate of gallium nitride, that a shielding layer is provided for forming a space charge zone for shielding of an electric field when the semiconductor component is connected in a blocking operating mode or a reverse direction, which layer includes gallium and/or nitrogen in addition to aluminum or indium, and the shielding layer is constructed or doped in such a way that at least one region effectively acting as a p-doped semiconductor is formed in the vicinity of a region effectively acting as an n-doped semiconductor. Thus, without the costly and disadvantageous ion implantation, a polarization doping can be produced that causes or enables the formation of a space charge zone.

Advantageous further embodiments of the semiconductor component according to the present invention are disclosed herein.

In a first, advantageous embodiment of the present invention, it can be provided that the shielding layer has or is formed from homogeneous, p-doped aluminum nitride, aluminum gallium nitride, indium nitride, or indium gallium nitride. The named materials can be integrated into a layer structure based on gallium nitride or on a substrate of gallium nitride with low effect. Furthermore, a p-doped material as a shielding layer facilitates the formation of a space charge zone in cooperation with an adjacent n-doped region, for example an n-doped region of a drift layer, preferably of n-doped gallium nitride.

In a further, advantageous embodiment of the present invention, it can be provided that the region effectively acting as a p-doped semiconductor is formed without the addition of foreign ions, in particular using only gallium and/or nitrogen and aluminum or indium. This has in particular the attractive advantage that only a very limited number of elements have to be used in the formation of the semiconductor component. Particularly advantageously, it can be provided that the shielding layer or the region effectively acting as a p-doped semiconductor has at least a gradual change in the aluminum content or the indium content in the direction of a layer thickness. In the context of the present invention, it has been recognized that the gradual change in the concentration of aluminum or indium, for example in a gallium nitride lattice or a gallium nitride matrix, leads to a change in polarization in different layer regions, resulting in a region with a negative polarization charge and an adjacent region with a positive polarization charge. As a result, positive charge carriers and negative charge carriers are attracted to the areas having respectively different polarity. Thus, given a depletion layer having a gradient of aluminum content or indium content, the shielding layer effectively acts like an n-doped semiconductor in a first part and like a p-doped semiconductor in an adjacent second part, without the doping with foreign ions having to take place or be provided. Accordingly, such a gradient can be used in a single or multiple formation in a semiconductor component as a shielding layer. The effective doping can be influenced or adjusted by setting the minimum and/or maximum content of aluminum or indium as well as via the spatial gradient.

Particularly advantageously, according to an example embodiment of the present invention, a multiple, in particular a double, gradual change of the aluminum content or of the indium content can be formed within the shielding layer. These multiple gradual changes can be realized both in interrupted and uninterrupted fashion. Also, the respective gradient and/or maximum and minimum concentrations of aluminum and indium can differ or be chosen differently for individual areas with a gradient. This allows the electric field to be modulated within the drift zone in blocking operation, thus further increasing the dielectric strength.

In a further, particularly advantageous embodiment of the present invention, it can be provided that the extension of the shielding layer in the vertical direction is as close as possible to a gallium nitride substrate, in particular is formed adjacent to a gallium nitride substrate. Particularly advantageously, the space charge zone can be formed with a large or even maximum distance from a channel of the semiconductor component or in as close proximity as possible to a drain contact or to a drain electrode. This also has a positive influence on the course of the electric field in blocking operation, and therefore results in a semiconductor component that can be operated at higher voltages. Furthermore, this configuration of the shielding layer can have advantageous effects with regard to the manufacturing process.

According to another advantageous embodiment of the present invention, the shielding layer forms a drift layer of a transistor situated on a gallium nitride substrate. In other words, this means that, for example, the regions of gradual changes in aluminum or indium content extend in the direction of a layer thickness over the entire layer thickness of a drift layer of a transistor. As a result, a particularly uniform or even distribution of the electric field can be achieved over the entire drift layer in the blocking state.

With regard to a method for producing a semiconductor component having two electrodes configured vertically one above the other on the basis of a gallium nitride substrate, it is provided in a method according to an example embodiment of the present invention that, in a multiplicity of method steps for forming, in particular depositing and/or structuring, a layer sequence on a gallium nitride substrate, a shielding layer is formed in a region which is situated indirectly between two electrodes configured vertically one above the other, aluminum or indium being deposited and/or doped in combination with gallium and/or nitrogen in such a way that at least one region effectively acting as a p-doped semiconductor is formed in the vicinity of a region effectively acting as an n-doped semiconductor.

As a result, a polarization doping can lead to the formation of a space charge zone and thus to the formation of a barrier layer. In a particularly advantageous embodiment of the method, it can be provided that for forming, in particular for depositing the shielding layer, an aluminum content or an indium content, preferably in a gallium nitride environment or gallium nitride matrix, is gradually varied over a layer thickness and along a layer thickness at least once between a minimum content and a maximum content and/or vice versa. Using conventional methods of layer growth for semiconductor components, the gradual change of the aluminum content or indium content during layer growth and thus along the layer thickness can be controlled and varied. Corresponding regions with different aluminum content or indium content can generate polarization charges, which in turn attract charge carriers and thus act effectively or outwardly like a correspondingly doped semiconductor.

According to a further, particularly preferred embodiment of the present invention, it can be provided that the shielding layer forms or occupies the entire drift layer of a transistor. In such a drift layer, a plurality of areas with gradual change of aluminum content or indium content can preferably follow each other in interrupted or uninterrupted fashion in the layer thickness direction.

Further advantages, features and details of the present invention result from the following description of preferred embodiments of the present invention and from the figures.

### BRIEF DESCRIPTION OF THE DRAWINGS

FIG. 1 shows a section through a vertical gallium nitride transistor according to the related art.

FIG. 2 shows a schematic representation of a shielding layer according to the present invention in a first example embodiment of the present invention.

FIG. 3 shows a schematic representation of a shielding layer according to the present invention, according to a second example embodiment of the present invention.

FIG. 4 shows a section through a vertical gallium nitride transistor according to a third example embodiment of the present invention.

### DETAILED DESCRIPTION OF EXAMPLE EMBODIMENTS

Identical elements or elements with the same function are provided with the same reference signs in the figures.

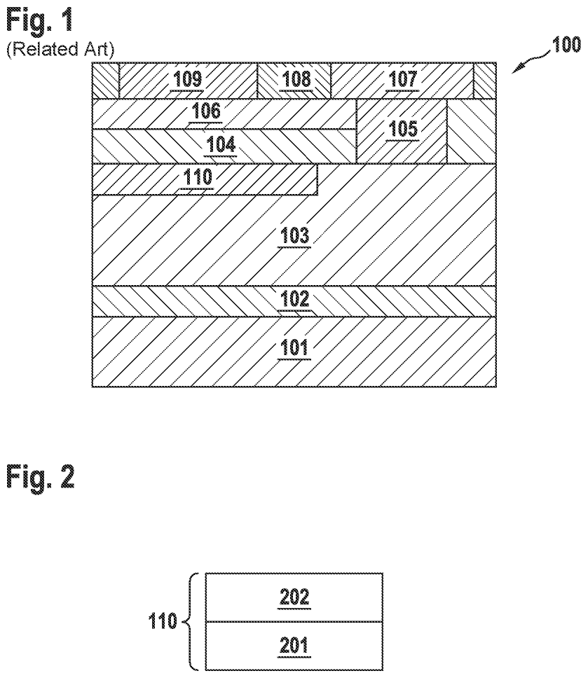

FIG. 1 shows the basic structure of a vertical gallium nitride component in the form of a vertical gallium nitride transistor 100. In the following, the present invention is described substantially with reference to a transistor. However, the present invention is equally suitable for other semiconductor components, such as semiconductor diodes.

For generic transistors 100, a metallic drain electrode 101 is typically provided on which a highly doped gallium nitride substrate 102 is situated, for example in the form of a gallium nitride wafer. A lightly doped, typically n-doped, gallium nitride drift layer 103 is grown or situated thereon. On top of the drift layer 103 there is a p-doped layer 104, which acts as a barrier layer.

In the case of a transistor 100, there is a region within the layer 104 in which, as a function of the wiring or voltage supply at the electrodes/contacts, a conductive channel is formed over regions 105, 106, region 106 typically being formed from a highly n-doped gallium nitride. Region 105 is connected or contacted to a source electrode 109. Source electrode 109 and gate electrode 107 are electrically separated by an insulating layer 108. In the on state, or conducting state, charge carriers flow from source electrode 109 into the highly doped region 106, through region 105 into drift layer 103, into the highly doped substrate 102, and finally into drain electrode 101. In the blocking case, region 105 does not conduct and a voltage applied to drain electrode 101 is blocked. In order to shield regions 105, 106 against the high electric fields occurring in the blocking case, so-called shielding areas 110 are typically used within drift layer 103. These are typically heavily p-doped gallium nitride regions and ensure that a maximum of the electric field in blocking operation is localized within drift layer 103 at the transition to shielding area 110 in a space charge zone.

In the related art, the p-doping of shielding layer 110 was realized by disadvantageous ion implantations, for example with magnesium ions.

FIG. 2 shows an illustration of a shielding layer 110 according to the present invention. For illustration, shielding layer 110 is divided into two regions. With regard to the material composition, however, there is no clear division into two parts; rather, an aluminum content in a gallium nitride matrix or in a gallium nitride lattice increases continuously and gradually from below in layer 201 until a maximum aluminum content is reached at the transition between layer 201 and 202, which is then gradually reduced again to a minimum content up to the upper edge of layer 202. This gradual change in the aluminum content in the gallium nitride lattice can produce a polarization doping. In particular, the change in polarization of layers 201, 202 results in negative polarization charges in layer 202 and positive polarization charges in layer 201. This attracts positive charge carriers into layer 202 and negative charge carriers into layer 201. Effectively, then, layer 202 will act like a p-doped semiconductor and layer 201 will act like an n-doped semiconductor without a doping with foreign ions having to take place or being provided.

As an alternative to a gradual change in the aluminum content or a corresponding indium content, shielding layer 110 can also be formed by homogeneous p-doped material of aluminum nitride, aluminum gallium nitride, indium nitride, or indium gallium nitride.

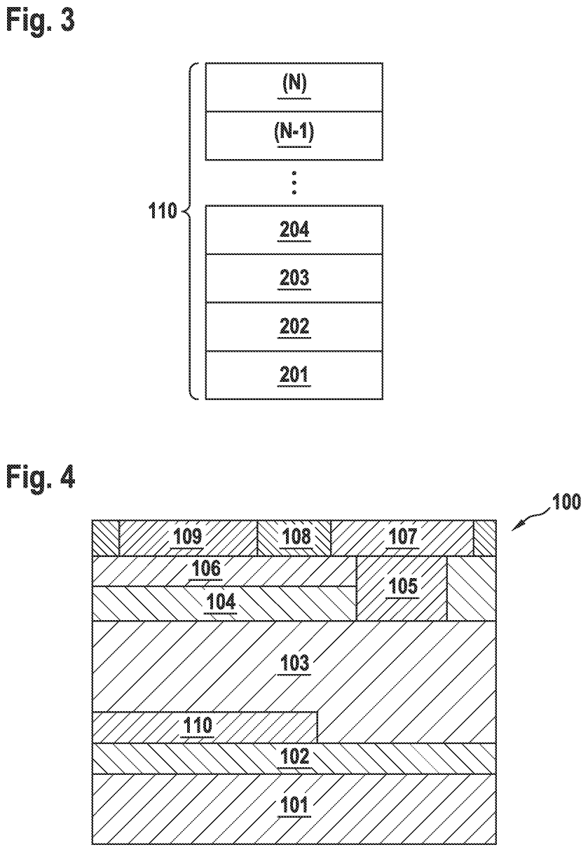

FIG. 3 shows a further advantageous embodiment in which, in a development of the embodiment of FIG. 2, a plurality of gradual changes of an aluminum content or indium content are varied in a gallium nitride environment. The variations can take place in interrupted or uninterrupted fashion. The maximum concentration or minimum concentration, as well as the spatial thickness of the gradient along the respective layer thickness with gradually changed aluminum or indium content, can also be different in different areas of the layer stack. Particularly preferably, such a layer stack can extend over the entire layer thickness of a drift layer 103 of a transistor.

FIG. 4 shows an embodiment of a vertical gallium nitride transistor according to the present invention. The configuration of the layers is essentially the same as the generic layer structure of FIG. 1. The main difference, however, is that shielding layer 110 is formed as close as possible to drain electrode 101, in particular immediately adjacent to gallium nitride substrate 102.

The formation there, which has a particularly advantageous influence on the distribution of the electric field and its maximum value in the blocking state, is also made possible by the fact that, according to the present invention, no ion implantation has to take place; rather, via homogeneously p-doped materials or material regions with corresponding gradients of an aluminum content or indium content, polarization charges are formed or exhibited, and a polarization doping can be formed based on this.

1-10. (canceled)

11. A semiconductor component, comprising:
two electrodes configured vertically one above the other;
a substrate made of gallium nitride (GaN);
a shielding layer for forming a space charge zone for shielding of an electric field when the semiconductor component is connected in a blocking operation or a reverse direction, wherein the shielding layer has gallium and/or nitrogen in addition to aluminum or indium, and is constructed or doped such that at least one region effectively acting as a p-doped semiconductor is formed in a vicinity of a region effectively acting as an n-doped semiconductor.

12. The semiconductor component as recited in claim 11, wherein the semiconductor component is a diode or transistor.

13. The semiconductor component as recited in claim 11, wherein the shielding layer has or is formed of homogeneous p-doped aluminum nitride (AlN), or aluminum gallium nitride (AlGaN), or indium nitride (InN), or indium gallium nitride (InGaN).

14. The semiconductor component as recited in claim 11, wherein the region effectively acting as a p-doped semiconductor is formed without an addition of foreign ions, using only: (i) gallium (Ga) and/or nitrogen (N), and (ii) aluminum (Al) or indium (In).

15. The semiconductor component as recited in claim 14, wherein the shielding layer has at least a gradual change in aluminum content or indium content in a direction of a layer thickness.

16. The semiconductor component as recited in claim 15, wherein the shielding layer has a double, gradual change in aluminum content or indium content.

17. The semiconductor component as recited in claim 15, wherein an extension of the shielding layer in a vertical direction is formed adjacent to the gallium nitride substrate.

18. The semiconductor component as recited in claim 15, wherein the shielding layer forms a drift layer of a transistor situated on the gallium nitride substrate.

19. A method for producing a semiconductor component having two electrodes configured vertically one above the other, the method comprising:
depositing a layer sequence on a gallium nitride substrate, including:
in a region that is situated indirectly between two electrodes configured vertically one above the other, forming a shielding layer in which aluminum or indium is deposited and/or doped with gallium and/or nitrogen in such a way that at least one region effectively acting as a p-doped semiconductor is formed in a vicinity of a region effectively acting as an n-doped semiconductor.

20. The method as recited in claim 19, wherein the semiconductor component is a diode or transistor.

21. The method as recited in claim 19, wherein during the formation of the shielding layer, an aluminum content or an indium content is gradually varied over a layer thickness at least once between a minimum content and a maximum content and/or between a maximum content and a minimum content.

22. The method as recited in claim 19, wherein with the shielding layer, an entire drift layer of a transistor is formed.
